(19) United States
(12) Patent Application Publication
(10) Pub. No.: US 2023/0010227 A1
(43) Pub. Date: Jan. 12, 2023

(54) SHALLOW TRENCH ISOLATION STRUCTURE AND METHOD FOR MANUFACTURING THE SAME

(71) Applicant: CHANGXIN MEMORY TECHNOLOGIES, INC., Hefei City (CN)

(72) Inventor: Mengzhu QIAO, Hefei (CN)

(21) Appl. No.: 17/517,761

(22) Filed: Nov. 3, 2021

Related U.S. Application Data
(63) Continuation of application No. PCT/CN2021/116917, filed on Sep. 7, 2021.

(30) Foreign Application Priority Data
Jul. 8, 2021 (CN) 202110776208.2

(51) Int. Cl. H01L 29/06; H01L 21/762

(52) U.S. Cl. CPC H01L 29/0653; H01L 21/76205

(57) ABSTRACT

Provided are a shallow trench isolation structure and a method for manufacturing the same. The shallow trench isolation structure includes a substrate, a first isolation structure, a second isolation structure and a third isolation structure. The substrate includes a first trench. The first isolation layer is located in the first trench and provided with a second trench. The second isolation layer is located in the second trench and provided with a third trench. The third isolation layer fills the third trench. The second trench is a V-shaped trench, and a bottom surface of the second isolation layer is a V-shaped surface that is adapted to a shape of the second trench.

### CROSS-REFERENCE TO RELATED APPLICATIONS

This is a continuation application of International Patent Application No. PCT/CN2021/116917, filed on Sep. 7, 2021, which claims priority to Chinese patent application No. 202110776208.2, filed to the State Intellectual Property Office of China on Jul. 8, 2021 and entitled “SHALLOW TRENCH ISOLATION STRUCTURE AND METHOD FOR MANUFACTURING THE SAME”. The disclosures of International Patent Application No. PCT/CN2021/116917 and Chinese patent application No. 202110776208.2 are hereby incorporated by reference in their entireties.

### BACKGROUND

A Dynamic Random Access Memory (DRAM) is a semiconductor memory that randomly writes and reads data at a high rate, and is widely applied to data storage apparatuses or devices.

A substrate of the DRAM device includes multiple spaced source/drain areas therein, and the adjacent source/drain areas are arranged an isolation area therebetween. There is typically arranged an isolation structure in the isolation area so as to isolate the adjacent source/drain areas. Most of isolation layers of the source/drain areas in the isolation area are manufactured by employing a Shallow Trench Isolation (STI) process.

However, the arrangement of the above-mentioned isolation layer cannot effectively reduce leakage between the adjacent source/drain areas.

### SUMMARY

The present disclosure relates to the technical field of semiconductor, in particular to a shallow trench isolation structure and a method for manufacturing the same.

The present disclosure provides a shallow trench isolation structure and a method for manufacturing the shallow trench isolation structure, which can effectively reduce leakage of the adjacent source/drain areas at the shallow trench isolation structure, thereby improving an isolation effect of the shallow trench isolation structure.

In a first aspect, the present disclosure provides a shallow trench isolation structure, which includes a substrate, a first isolation layer, a second isolation layer and a third isolation layer.

The substrate includes a first trench.

The first isolation layer is located in the first trench, and the first isolation layer is provided with a second trench.

The second isolation layer is located in the second trench, and the second isolation layer is provided with a third trench.

The third isolation layer fills the third trench.

The second trench is a V-shaped trench, and a bottom surface of the second isolation layer is a V-shaped surface that is adapted to a shape of the second trench.

The shallow trench isolation structure provided by the present disclosure isolates the adjacent source/drain areas by arranging the first isolation layer, the second isolation layer and the third isolation layer and employing the three isolation layers to form a barrier structure, so as to avoid the leakage between the adjacent source/drain areas. By arranging the second trench as the V-shaped trench and the bottom surface of the second isolation layer as the V-shaped surface that is adapted to the shape of the second trench, holes collected at the bottom surface of the second isolation layer are reduced, so as to avoid the leakage generated at an interface between the second isolation layer and the first isolation layer due to holes collection, thereby improving the isolation effect of the shallow trench isolation structure.

In a second aspect, the present disclosure further provides a method for manufacturing a shallow trench isolation structure, which includes the following operations.

A first trench is formed in a substrate.

A first isolation layer provided with a second trench is formed in the first trench.

A second isolation layer provided with a third trench is formed in the second trench.

A third isolation layer is formed in the third trench.

The second trench is a V-shaped trench, and a bottom surface of the second isolation layer is a V-shaped surface that is adapted to a shape of the second trench.

The method for manufacturing the shallow trench isolation structure provided by the present disclosure isolates the adjacent source/drain areas by sequentially forming the first isolation layer, the second isolation layer and the third isolation layer in the first trench and employing the three isolation layers to form a barrier structure, so as to avoid leakage between the adjacent source/drain areas. By arranging the second trench as the V-shaped trench and the bottom surface of the second isolation layer as the V-shaped surface that is adapted to the shape of the second trench, holes collected at the bottom surface of the second isolation layer are reduced, so as to avoid the leakage generated at an interface between the second isolation layer and the first isolation layer due to holes collection, thereby improving an isolation effect of the shallow trench isolation structure.

The construction, as well as other invention objects and beneficial effects of the present disclosure will appear more fully in conjunction with the accompanying drawings and the description of preferred embodiments.

### BRIEF DESCRIPTION OF THE DRAWINGS

In order to describe the technical solutions in the embodiments of the present disclosure or a related art more clearly, the drawings required to be used in the description of the embodiments or the related art will be briefly introduced below. It is apparent that the drawings in the following description are merely some embodiments of the present disclosure. Those of ordinary skill in the art may further obtain other drawings according to these drawings without creative work.

FIG. 1 is a schematic structural diagram of a shallow trench isolation structure in a related art.

FIG. 2 is a schematic structural diagram in which a SiO₂ oxide layer is formed in a substrate in a related art.

FIG. 3 is a schematic structural diagram in which a SiO₂ oxide layer and a SiN liner layer are formed in a substrate in a related art.

FIG. 4 is a schematic structural diagram in which a SiO₂ oxide layer, a SiN liner layer and a dielectric material are formed in a substrate in a related art.

FIG. 5 is a schematic structural diagram of a shallow trench isolation structure provided by an embodiment of the present disclosure.

FIG. 6 is a schematic structural diagram of a substrate having a first trench in a shallow trench isolation structure provided by an embodiment of the present disclosure.

FIG. 7 is a schematic structural diagram in which a first isolation layer that has a recess portion is formed in a first trench of a shallow trench isolation structure provided by an embodiment of the present disclosure.

FIG. 8 is a schematic structural diagram in which a first isolation layer that has a second trench is formed in a first trench of a shallow trench isolation structure provided by an embodiment of the present disclosure.

FIG. 9 is a schematic structural diagram in which a second isolation layer that has a third trench is formed in a second trench of a shallow trench isolation structure provided by an embodiment of the present disclosure.

FIG. 10 is a schematic structural diagram in which a third isolation layer is formed in a third trench of a shallow trench isolation structure provided by an embodiment of the present disclosure.

FIG. 11 is a schematic structural diagram of another shallow trench isolation structure provided by an embodiment of the present disclosure.

FIG. 12 is a schematic flowchart of a method for manufacturing a shallow trench isolation structure provided by an embodiment of the present disclosure.

FIG. 13 is a schematic flowchart in which a first isolation layer is formed of a method for manufacturing a shallow trench isolation structure provided by an embodiment of the present disclosure.

FIG. 14 is a schematic flowchart in which a second isolation layer is formed of a method for manufacturing a shallow trench isolation structure provided by an embodiment of the present disclosure.

### DETAILED DESCRIPTION

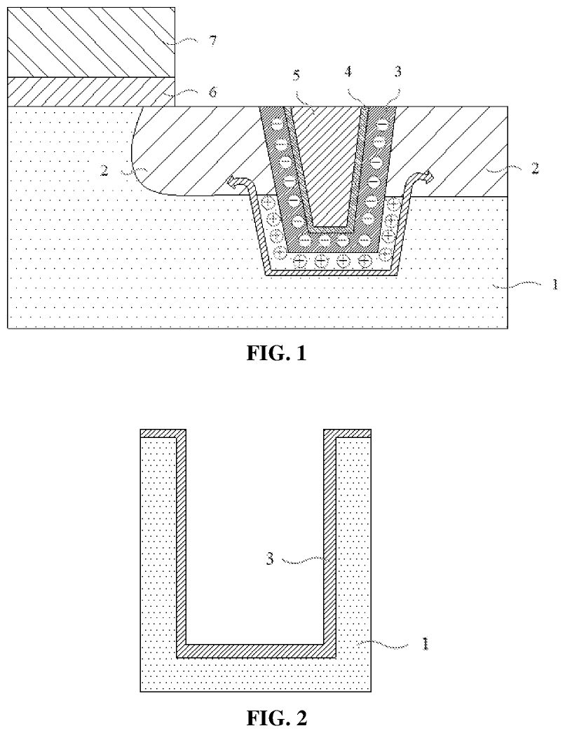

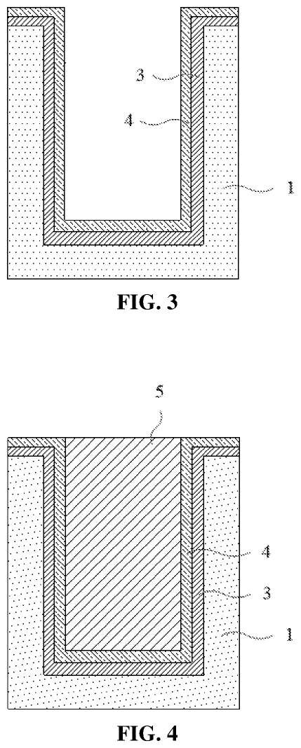

In practical studying process, inventors of the present disclosure have found that an isolation structure is arranged between adjacent source/drain areas in a substrate of a Dynamic Random Access Memory (DRAM) device, the isolation structure is manufactured by a shallow trench isolation process. FIG. 1 is a schematic structural diagram of a shallow trench isolation structure in a related art. FIG. 2 is a schematic structural diagram in which a SiO₂ oxide layer is formed in a substrate in a related art. FIG. 3 is a schematic structural diagram in which a SiO₂ oxide layer and a SiN liner layer are formed in a substrate in a related art. FIG. 4 is a schematic structural diagram in which a SiO₂ oxide layer, a SiN liner layer and a dielectric material are formed in a substrate in a related art.

Referring to FIG. 1 to FIG. 4, a source/drain area 2 is provided in a substrate 1 of a DRAM device, and the source/drain area 2 may be a source/drain area 2 of a P-type channel Metal-Oxide-Semiconductor (PMOS) transistor or a N-type channel Metal-Oxide-Semiconductor (NMOS) transistor. A trench is formed between the adjacent source/drain areas 2 (not shown in figures). In conjunction with FIG. 2 to FIG. 4, a SiO₂ oxide layer 3, a SiN liner layer 4 and a dielectric material 5 are sequentially formed in the trench, and the SiO₂ oxide layer 3, the SiN liner layer 4 and the dielectric material 5 jointly constitute a shallow trench isolation structure. A source area and a drain area of an active area have a channel area therebetween, and a gate oxide layer 6 and a gate layer 7 are formed over the channel area.

In a process of the feature size of the DRAM device decreasing continuously, taking the PMOS transistor as an example, a strong electric field results in generation of hot carriers in the highly integrated PMOS transistor. Based on a fact that the hot carriers typically have high energy, the hot carriers may pass through the SiO₂ oxide layer 3 into the shallow trench isolation structure.

The hot carriers penetrating into the shallow trench isolation structure are easily trapped at an interface between the SiO₂ oxide layer 3 and the SiN liner layer 4, which results in a large number of holes collected at the interface, thereby causing leakage near the shallow trench isolation structure. The leakage will result in deterioration in stability of the source/drain areas 2 of the adjacent PMOS transistors.

The inventors analyze that the cause of the above-mentioned leakage is mainly as follows. In the shallow trench isolation structure, the SiO₂ oxide layer 3 has a long planar extension segment, that is, the SiO₂ oxide layer 3 below the SiN liner layer 4, the planar extension segment of the SiO₂ oxide layer 3 results in a relatively large contact area between the SiO₂ oxide layer 3 and the substrate 1 (Si), so that there are a large number of hot carriers collected at the interface between the planar extension segment of the SiO₂ oxide layer 3 and the substrate 1 (Si), that is, the large number of collected holes causes a large leakage here.

In view of this, the shallow trench isolation structure and the method for manufacturing the shallow trench isolation structure provided by the embodiments of the present disclosure isolates the adjacent source/drain areas by arranging a first isolation layer, a second isolation layer and a third isolation layer in the shallow trench isolation structure and employing the three isolation layers to form a barrier structure, so as to avoid the leakage between the adjacent source/drain areas. By arranging a second trench as a V-shaped trench and a bottom surface of the second isolation layer as a V-shaped surface that is adapted to the shape of the second trench, holes collected at the bottom surface of the second isolation layer are reduced, so as to avoid the leakage generated at an interface between the second isolation layer and the first isolation layer due to holes collection, thereby improving an isolation effect of the shallow trench isolation structure.

In order to make the objects, technical solutions and advantages of the present disclosure clearer, the technical solutions in the embodiments of the present disclosure will be described below in more detail with reference to the accompanying drawings in the preferred embodiments of the present disclosure. In the drawings, the same or similar reference numerals refer to the same or similar components or the components having the same or similar functions throughout. The described embodiments are part of but not all the embodiments of the present disclosure. The embodiments described below by reference to the drawings are exemplary, are intended to explain the present disclosure and should not be construed as a limitation to the present disclosure. On the basis of the embodiments in the present disclosure, all other embodiments obtained by those skilled in the art without any creative effort fall within the protection scope of the present disclosure. The embodiments of the present disclosure will be described below in detail with reference to the accompanying drawings.

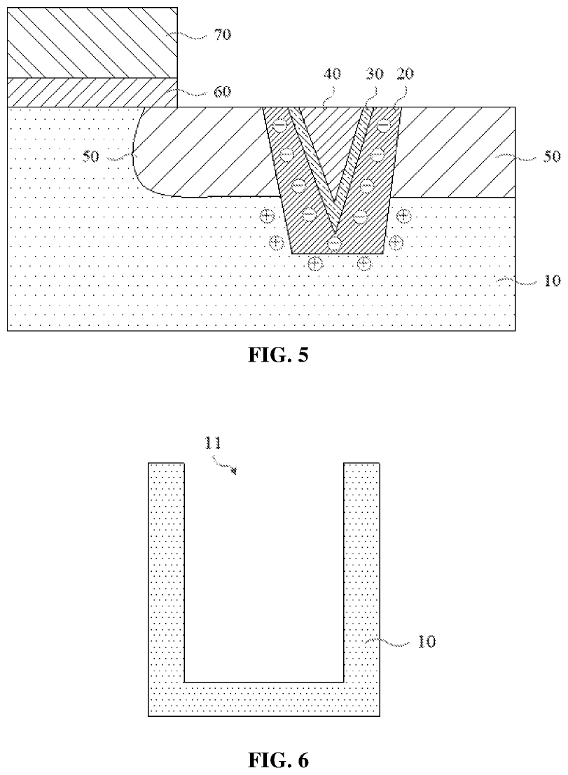

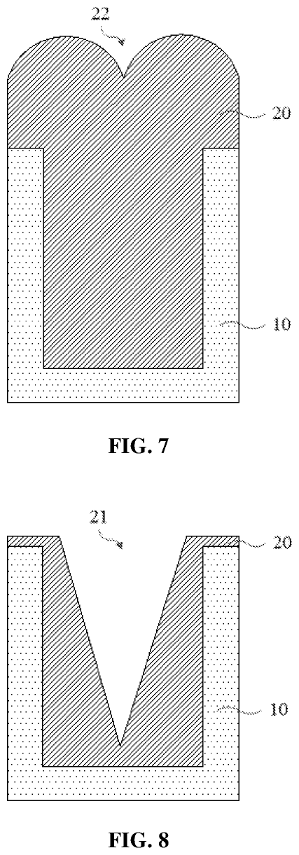

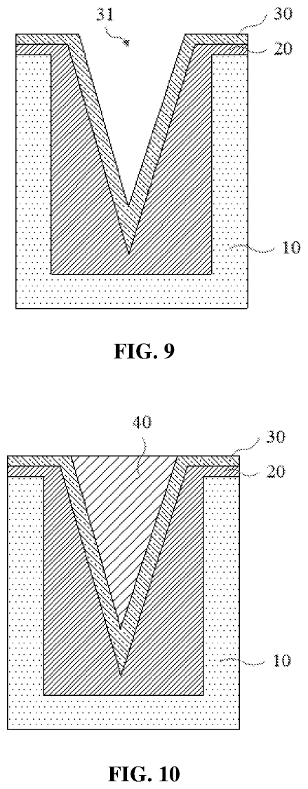

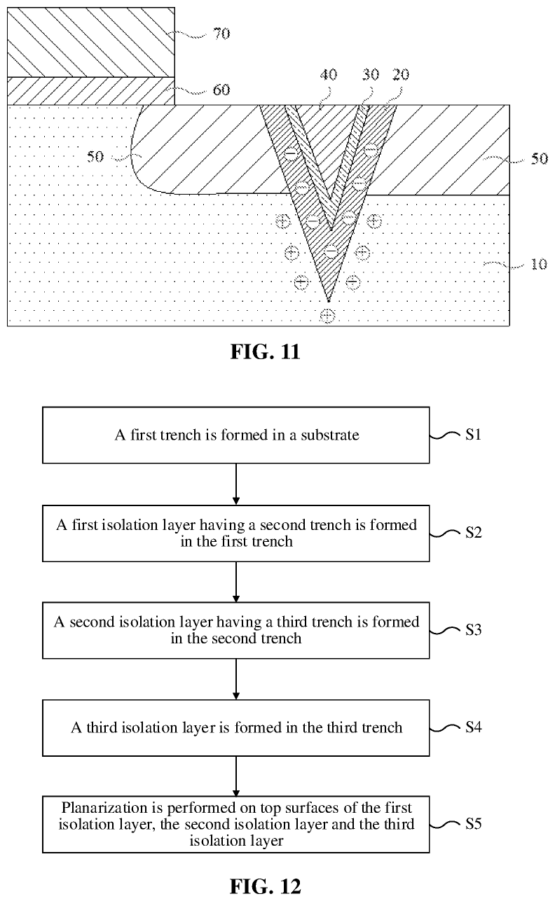

FIG. 5 is a schematic structural diagram of a shallow trench isolation structure provided by an embodiment of the present disclosure. FIG. 6 is a schematic structural diagram of a substrate having a first trench in a shallow trench isolation structure provided by an embodiment of the present disclosure. FIG. 7 is a schematic structural diagram in which a first isolation layer that has a recess portion is formed in a first trench of a shallow trench isolation structure provided by an embodiment of the present disclosure. FIG. 8 is a schematic structural diagram in which a first isolation layer that has a second trench is formed in a first trench of a shallow trench isolation structure provided by an embodiment of the present disclosure. FIG. 9 is a schematic structural diagram in which a second isolation layer that has a third trench is formed in a second trench of a shallow trench isolation structure provided by an embodiment of the present disclosure. FIG. 10 is a schematic structural diagram in which a third isolation layer is formed in a third trench of a shallow trench isolation structure provided by an embodiment of the present disclosure. FIG. 11 is a schematic structural diagram of another shallow trench isolation structure provided by an embodiment of the present disclosure.

Referring to FIG. 5, the shallow trench isolation structure provided by the embodiments of the present disclosure includes a substrate 10, a first isolation layer 20, a second isolation layer 30 and a third isolation layer 40.

The substrate 10 includes a first trench 11. The first isolation layer 20 is located in the first trench 11, and the first isolation layer 20 has a second trench 21. The second isolation layer 30 is located in the second trench 21, and the second isolation layer 30 has a third trench 31. The third isolation layer 40 fills the third trench 31.

The second trench 21 is a V-shaped trench, and a bottom surface of the second isolation layer 30 is a V-shaped surface that is adapted to a shape of the second trench 21.

It is to be noted that the substrate 10 in the shallow trench isolation structure provided by the present embodiment may provide a support base for the rest of structure layers arranged on the substrate 10. The substrate 10 may be silicon, that is, may be single crystal silicon, polysilicon, amorphous silicon, silicon germanium compound or Silicon-On-Insulator (SOI) or other materials known to those skilled in the art.

The substrate 10 may have a semiconductor layer therein, the semiconductor layer forms an active area of the substrate 10, the active area includes a source area and a drain area, and a channel area is formed between the source area and the drain area. That is, the substrate 10 has spaced source/drain areas 50, the first trench 11 is located between the adjacent source/drain areas 50, an isolation area may be formed between the adjacent source/drain areas 50, and the above-mentioned shallow trench isolation structure may be arranged within the isolation area.

The first trench 11 may be formed between the adjacent source/drain areas 50 in the substrate 10, and the first trench 11 may isolate the adjacent source/drain areas 50 in terms of structure. At the same time, the first isolation layer 20, the second isolation layer 30 and the third isolation layer 40 will be sequentially formed in the first trench 11, and the three isolation layers jointly constitute a main isolation structure of the shallow trench isolation structure.

Specifically, the second isolation layer 30 is formed in the second trench 21 on the first isolation layer 20, and the third isolation layer 40 is formed in the third trench 31 on the second isolation layer 30. Such arrangement may ensure that the first isolation layer 20, the second isolation layer 30 and the third isolation layer 40 are stably arranged in the first trench 11 and the degree of interference therebetween is relatively low.

It is to be noted that, in the present embodiment, the second trench 21 is a V-shaped trench, that is, the bottom of the second trench 21 is the tip of the V-shaped trench, and the second isolation layer 30 is filled in the second trench 21 so that the bottom surface of the second isolation layer 30 has a V-shaped surface that is adapted to the shape of the second trench 21.

In the present embodiment, the bottom of the second trench 21 and the bottom surface of the second isolation layer 30 do not have the planar extension segment in the related art as shown in FIG. 1. Therefore, the number of holes that can be collected between the second isolation layer 30 and the substrate 10 (Si) is reduced, and the leakage that can be caused by the holes is reduced, thereby improving the isolation effect of the shallow trench isolation structure.

Specifically, in the present embodiment, a PMOS transistor is formed in the source/drain area 50, that is, the source/drain area 50 is a source/drain area 50 of the PMOS transistor. The PMOS transistor further includes a gate oxide layer 60 and a gate layer 70 formed on the substrate 10. The above-mentioned shallow trench isolation structure may isolate the adjacent source/drain areas 50 of PMOS transistors, so as to prevent hot carriers in the PMOS transistors from penetrating the gate oxide layer 60 into the shallow trench isolation structure. Further, the hot carriers is prevented from being trapped at the interface of the adjacent isolation layers of the shallow trench isolation structure, mainly prevented them from being trapped at the interface between the first isolation layer 20 and the second isolation layer 30. Therefore, the above-mentioned way may reduce the leakage generated at the interface due to the hot carrier collection, and improve the isolation effect of the source/drain areas 50 of the adjacent PMOS transistors.

As a realizable embodiment, a material of the first isolation layer 20 is the same as a material of the third isolation layer 40, and the material of the first isolation layer 20 includes silicon oxide. The material of the first isolation layer 20 is different from a material of the second isolation layer 30, and the material of the second isolation layer 30 includes silicon nitride.

It is to be noted that the material of the first isolation layer 20 is the same as the material of the third isolation layer 40, which may alleviate difficulty for manufacturing the shallow trench isolation structure. Further, the first isolation layer 20 is in contact with the substrate 10, and the first isolation layer 20 is selected as silicon oxide, which is highly fused to the interface bonded to the silicon substrate 10. Therefore, the stability of the interface between the first isolation layer 20 and the substrate 10 is relatively high.

Further, the second isolation layer 30 is selected as silicon nitride, or may be selected as silicon oxycarbide. The electrical isolation effect of silicon nitride is better, and the stability of the interface between the silicon nitride and the silicon oxide of the first isolation layer 20 is relatively high.

As a realizable embodiment, the thicknesses of the second isolation layer 30 are the same at different positions of the second trench 21. It is to be noted that the equal thickness of the second isolation layer 30 may improve the uniformity of the second isolation layer 30. At the same time, the third isolation layer 40 is formed in the third trench 31 on the second isolation layer 30. Therefore, the relatively uniform second isolation layer 30 may facilitate the arrangement of the third isolation layer 40, thereby improving the structural stability of the shallow trench isolation structure as a whole.

Based on the above-mentioned structure, the structure of the first trench 11 may be adjusted to reach the purpose of further reducing the leakage at the shallow trench isolation structure.

Specifically, referring to FIG. 5, the first trench 11 is a trapezoidal trench, and a cross-sectional area of the first trench 11 gradually increases in a direction from a bottom of the first trench 11 to an opening of the first trench 11. A bottom surface of the first isolation layer 20 has a planar extension segment.

It is to be noted that, in the related art, the trench of the shallow trench isolation structure is typically arranged as a rectangular trench, that is, a width of an opening of the trench is substantially the same as a width of a bottom of the trench. The above-mentioned arrangement of the present embodiment may, based on the related art, reduce a width of the bottom of the first trench 11, that is, a length of the planar extension segment of the first isolation layer 20 is reduced, which facilitate to reduce the possibility of holes collection here, thereby reducing the leakage here.

Referring to FIG. 11, the first trench 11 is a V-shaped trench, and the bottom surface of the first isolation layer 20 is a V-shaped surface. The first trench 11 may be provided to have the same shape as the second trench, in this way, the bottom of the first trench 11 is the tip of the V-shaped trench, and the bottom surface of the first isolation layer 20 is an adapted V-shaped surface. Therefore, there is no the above-mentioned planar extension segment at the bottom surface of the first isolation layer 20. The leakage caused by holes collection between the first isolation layer 20 and the second isolation layer 30 is less likely to exist at the bottom surface of the first isolation layer 20, so the leakage here may be effectively reduced, and the isolation effect at the first trench 11 and the first isolation layer 20 is improved.

Based on the above-mentioned structure, the structure of the third trench 31 may be adjusted to reach the purpose of further reducing the leakage at the shallow trench isolation structure.

Specifically, the third trench 31 is a trapezoidal trench, and a cross-sectional area of the third trench 31 gradually increases in a direction from a bottom of the third trench 31 to an opening of the third trench 31. A top surface of the second isolation layer 30 has a planar extension segment.

It is to be noted that, in the related art, a trench is typically provided on the SiN liner layer 4 for the dielectric material 5 to fill, the trench here is typically a rectangular trench, that is, a width of an opening of the trench is substantially the same as a width of a bottom of the trench. The above-mentioned arrangement of the present embodiment may, based on the related art, reduce the width of the bottom of the third trench 31, that is, a length of the planar extension segment of the third isolation layer 40 is reduced, which facilitate to reduce the holes collection between the second isolation layer 30 and the third isolation layer 40, thereby reducing the generation of the leakage here.

Referring to FIG. 5 and FIG. 11, the third trench 31 is a V-shaped trench, and the top surface of the second isolation layer 30 is a V-shaped surface. The third trench 31 may be provided to have the same shape as the second trench 21, in this way, the bottom of the third trench 31 is the tip of the V-shaped trench, and the top surface of the second isolation layer 30 or the bottom surface of the third isolation layer 40 is an adapted V-shaped surface. In this way, the holes collection at the interface between the third isolation layer 40 and the second isolation layer 30 may be reduced, which facilitates to reduce the leakage formed here, thereby improving the isolation effect at the third trench 31, the second isolation layer 30 and the third isolation layer 40.

Based on the above-mentioned embodiments, referring to FIG. 12 to FIG. 14, in conjunction to FIG. 5 to FIG. 10 at the same time, the present disclosure further provides a method for manufacturing a shallow trench isolation structure, which includes the following operation.

In S1, a first trench is formed in a substrate. It is to be noted that, referring to FIG. 6, the first trench 11 may be formed by using a mask plate+photolithography manner, that is, a hard mask plate and photoresist are sequentially formed on the substrate 10, a mask pattern is transferred to the hard mask plate by a high selectivity etching, and then is transferred onto the substrate 10, so that the first trench 11 is formed.

In S2, a first isolation layer having a second trench is formed in the first trench.

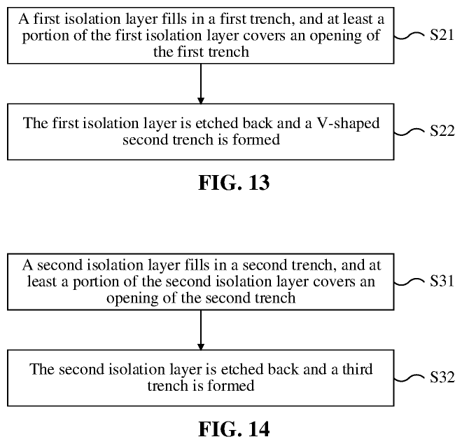

In S2, referring to FIG. 13, the following operations may be specifically included.

In S21, the first isolation layer fills in the first trench, and at least a portion of the first isolation layer covers an opening of the first trench. The first isolation layer 20 may be formed by deposition, such as an atomic layer deposition method. Of course, in practical use, the method for manufacturing the first isolation layer 20 may further include an in-situ steam generation method and a spin coating method, so as to ensure that the first isolation layer 20 fills up the first trench 11 and covers the opening of the first trench 11 at the same time.

Referring to FIG. 7, a top surface of the first isolation layer 20 has a recess portion 22. The recess portion 22 is formed by a step effect of deposition in the deposition process. That is, the deposition rate of the first isolation layer 20 closer to a center position of the first trench 11 is relatively low, and the deposition rate of the first isolation layer 20 closer to an edge position of the first trench 11 is relatively high. Based on a difference in the deposition rates at different positions in the first trench 11, the recess portion 22 is formed. The recess portion 22 may serve as a structure base for etching back the first isolation layer 20.

In S22, the first isolation layer is etched back and a V-shaped second trench is formed. Specifically, referring to FIG. 8, the first isolation layer 20 is etched back along the recess portion 22 and the V-shaped second trench 21 is formed. In this way, the difficulty of forming the second trench 21 by etch-back may be effectively reduced.

In S3, a second isolation layer having a third trench is formed in the second trench.

In S3, referring to FIG. 9 and FIG. 14, the following operations are specifically included.

In S31, the second isolation layer fills in the second trench, and at least a portion of the second isolation layer covers an opening of the second trench. The formation of the second isolation layer 30 may be the same as the formation of the first isolation layer 20. The second trench 21 is a V-shaped trench, and a bottom surface of the second isolation layer 30 is a V-shaped surface that is adapted to the shape of the second trench 21. In this way, the leakage at the bottom surface of the second isolation layer 30 may be reduced.

In S32, the second isolation layer is etched back and a third trench is formed. The thicknesses of the second isolation layer 30 are equal at different positions of the second trench 21. Such an arrangement may improve the uniformity of the second isolation layer 30. In order to meet requirements of the thickness of the second isolation layer 30, the process of etching back the second isolation layer 30 may select a dry etching method to improve the accuracy of the etch-back.

In S4, a third isolation layer is formed in the third trench. Specifically, referring to FIG. 10, the third isolation layer 40 fills up the third trench 31. In this way, the stability of the third trench 31 may be improved, so as to ensure the structural stability of the shallow trench isolation structure as a whole. The formation of the third isolation layer 40 may be the same as those of the first isolation layer 20 and the second isolation layer 30.

Further, after the operation in S4, the following operation may be further included. Planarization is performed on top surfaces of the first isolation layer 20, the second isolation layer 30 and the third isolation layer 40. Such a processing manner facilitates arrangement of the rest layer structure over the substrate 10. The planarization process may be completed by etching, so that the top surfaces of the first isolation layer 20, the second isolation layer 30 and the third isolation layer 40 are flush with the top surface of the substrate 10 (the structure is not shown in figures) finally.

The method for manufacturing the shallow trench isolation structure provided by embodiments of the present disclosure isolates the adjacent source/drain areas 50 by sequentially forming the first isolation layer 20, the second isolation layer 30 and the third isolation layer 40 in the first trench 11 and employing the three isolation layers to form a barrier structure, so as to avoid leakage between the adjacent source/drain areas 50. By arranging the second trench 21 as the V-shaped trench, and the bottom surface of the second isolation layer 30 as the V-shaped surface that is adapted to the shape of the second trench 21, holes collected at the bottom surface of the second isolation layer 30 are reduced, so as to avoid the leakage generated at an interface between the second isolation layer 30 and the first isolation layer 20 due to holes collection, thereby improving the isolation effect of the shallow trench isolation structure.

Based on the above, the present embodiment further provides a semiconductor structure, which may be a DRAM device. The semiconductor structure, based on the above-mentioned substrate, may further include a bit line located in the substrate, and a word line, a transistor structure and a capacitor structure located on the substrate.

The DRAM device includes an array of multiple storage units on the substrate, and each of the storage units includes a capacitor structure and a transistor structure. The capacitor structure is configured to store data while the transistor structure may control the capacitor to access to the data, and a gate layer of the transistor structure is connected to the word line. The drain area in the substrate is connected to the bit line structure, and the source area is connected to the capacitor structure. A voltage signal on the word line may control on or off state of the transistor structure, and then data information stored in the capacitor structure is read through the bit line or the data information is written into the capacitor structure for storage through the bit line, so as to achieve data access of the DRAM device. Therefore, the application of the substrate containing the above-mentioned shallow trench isolation structure in the DRAM device may improve the stability of the DRAM device, thereby improving the access performance of the DRAM device.

In the above description, it will be appreciated that, unless expressly specified and limited otherwise, the terms “mounted”, “linked”, and “connected” are to be interpreted broadly, for example, may be a fixed connection, may be an indirect connection through an intermediary, and may also be an internal communication between two elements or an interaction relationship between two elements. The specific meaning of the above terms in the present disclosure may be understood by those of ordinary skill in the art according to specific situations. The terms “upper”, “lower”, “front”, “rear”, “vertical”, “horizontal”, “top”, “bottom”, “inner”, “outer”, or the like refer to orientations or location relationships on the basis of the orientations or the location relationships shown in the drawings, are merely intended to facilitate the description of the present disclosure and to simplify the description, and are not intended to indicate or imply that a device or element referred to must have a specific orientation or be configured and operated in a specific orientation, so that the terms should not be construed as a limitation to the present disclosure. In the description of the present disclosure, “multiple (a plurality of)” means two or more unless specifically stated otherwise.

The terms “first”, “second”, “third”, “fourth” and the like (if present) in the specification and claims of the present disclosure and in the above drawings are used to distinguish similar objects and unnecessarily used to describe a specific sequence or sequential order. It will be appreciated that such data used in this way may be interchangeable where appropriate, so that the embodiments of the present disclosure described herein can be, for example, implemented in a sequence except for those illustrated or described herein. In addition, the terms “include” and “have”, as well as any variations thereof, are intended to cover a non-exclusive inclusion, for example, a process, a method, a system, a product or a device that includes a series of steps or elements is not necessarily limited to those expressly listed steps or elements, but may include other steps or elements that are not expressly listed or inherent to such process, method, product, or device.

Finally, it is to be noted that the above embodiments are merely used to describe the technical solutions of the present disclosure and are not intended to limit the present disclosure. Although the present disclosure has been described in detail with reference to the foregoing embodiments, those skilled in the art will appreciate that the technical solutions described in the above embodiments may still be modified or part or all of the technical features thereof may be equivalently replaced. These modifications and replacements do not depart the essence of the corresponding technical solutions from the scope of the technical solutions of the embodiments of the present disclosure.

1. A shallow trench isolation structure, comprising:
a substrate comprising a first trench;
a first isolation layer located in the first trench and provided with a second trench;
a second isolation layer located in the second trench and provided with a third trench; and
a third isolation layer filling the third trench,
wherein the second trench is a V-shaped trench, a bottom surface of the second isolation layer is a V-shaped surface that is adapted to a shape of the second trench.

2. The shallow trench isolation structure of claim 1, wherein the first trench is a trapezoidal trench, a cross-sectional area of the first trench gradually increases in a direction from a bottom of the first trench to an opening of the first trench; and
a bottom surface of the first isolation layer has a planar extension segment.

3. The shallow trench isolation structure of claim 1, wherein the first trench is a V-shaped trench, and a bottom surface of the first isolation layer is a V-shaped surface.

4. The shallow trench isolation structure of claim 2, wherein the third trench is a trapezoidal trench, a cross-sectional area of the third trench gradually increases in a direction from a bottom of the third trench to an opening of the third trench; and
a top surface of the second isolation layer has a planar extension segment.

5. The shallow trench isolation structure of claim 2, wherein the third trench is a V-shaped trench, and a top surface of the second isolation layer is a V-shaped surface.

6. The shallow trench isolation structure of claim 1, wherein a material of the first isolation layer is the same as a material of the third isolation layer, and the material of the first isolation layer is different from a material of the second isolation layer.

7. The shallow trench isolation structure of claim 1, wherein a material of the first isolation layer comprises silicon oxide, and a material of the second isolation layer comprises silicon nitride.

8. The shallow trench isolation structure of claim 1, wherein a thickness of the second isolation layer is equal at different positions of the second trench.

9. The shallow trench isolation structure of claim 1, wherein the substrate has spaced source/drain areas, the first trench is located between adjacent source/drain areas; and
the source/drain areas have PMOS transistors formed therein.

10. A method for manufacturing a shallow trench isolation structure, comprising:
forming a first trench in a substrate;
forming a first isolation layer having a second trench in the first trench;
forming a second isolation layer having a third trench in the second trench; and
forming a third isolation layer in the third trench;
wherein the second trench is a V-shaped trench, a bottom surface of the second isolation layer is a V-shaped surface that is adapted to a shape of the second trench.

11. The method for manufacturing the shallow trench isolation structure of claim 10, wherein the operation of forming the first isolation layer having the second trench in the first trench comprises:
filling the first isolation layer in the first trench, at least a portion of the first isolation layer covering an opening of the first trench; and
etching back the first isolation layer and forming the V-shaped trench.

12. The method for manufacturing the shallow trench isolation structure of claim 10, wherein the operation of forming the second isolation layer having the third trench in the second trench comprises:
filling the second isolation layer in the second trench, at least a portion of the second isolation layer covering an opening of the second trench; and
etching back the second isolation layer and forming the third trench, a thickness of the second isolation layer being equal at different positions of the second trench.

13. The method for manufacturing the shallow trench isolation structure of claim 10, wherein the operation of forming the third isolation layer in the third trench comprises:
filling up the third trench with the third isolation layer.

14. The method for manufacturing the shallow trench isolation structure of claim 10, wherein after the operation of forming the third isolation layer in the third trench, the method further comprises:
performing planarization on top surfaces of the first isolation layer, the second isolation layer and the third isolation layer.

15. The method for manufacturing the shallow trench isolation structure of claim 11, wherein in the operation of filling the first isolation layer in the first trench, at least the portion of the first isolation layer covering the opening of the first trench, a top surface of the first isolation layer has a recess portion; and
the operation of etching back the first isolation layer and forming the V-shaped trench comprises:
etching back the first isolation layer along the recess portion and forming the V-shaped trench.

16. The method for manufacturing the shallow trench isolation structure of claim 10, wherein a method for manufacturing the first isolation layer comprises one of an atomic layer deposition method, an in-situ steam generation method and a spin coating method.
